(19) United States
(12) Patent Application Publication
(10) Pub. No.: US 2023/0185530 A1
(43) Pub. Date: Jun. 15, 2023

(54) Method for the Analogue Multiplication and/or Calculation of a Scalar Product with a Circuit Assembly, in Particular for Artificial Neural Networks

(71) Applicant: Universität Stuttgart, Stuttgart (DE)

(72) Inventor: Markus GRÖZING, Stuttgart (DE)

(21) Appl. No.: 17/925,048

(22) PCT Filed: May 10, 2021
(86) PCT No.: PCT/EP2021/062305

§ 371 Date: Nov. 14, 2022

(30) Foreign Application Priority Data
May 14, 2020 (DE) 10 2020 133 088.0

(51) Int. Cl. G06F 7/523; G06F 7/544; H03M 1/82

(52) U.S. Cl. CPC G06F 7/523; G06F 7/5443; H03M 1/82

(57) ABSTRACT

The present invention relates to a method for the analogue multiplication and/or calculation of a scalar product, with a circuit assembly, which has a series circuit comprising a first FET and a second FET, or FET array, serving as a current source, a charging device, and a capacitance, which can be precharged by way of the charging device, and can be discharged by way of the series circuit of the first FET and the second FET, or FET array. The capacitance is initially precharged for the multiplication of a first value by a second value. The first value, encoded as the pulse width of a voltage pulse, is applied to the gate of the first FET, and the second value, encoded as the voltage amplitude, is applied to the gate of the second FET. By this means the capacitance is discharged, for the period of time of the voltage pulse, with a discharge current, which is specified by the voltage amplitude applied to the second FET. The result of the multiplication can then be determined from the residual charge or residual voltage of the capacitance. The method operates very energy-efficiently and can advantageously be used for the execution of calculations in neurons of an artificial neural network.

### TECHNICAL FIELD OF APPLICATION

The present invention relates to a method for the analogue multiplication and/or for the analogue calculation of a scalar product, formed by multiplication of a first value by a second value of a respective value pair, and summation of results of the multiplication for a plurality of value pairs, with a circuit assembly. The invention also relates to the application of the method in an artificial neural network (ANN).

In electronic signal processing, most circuit parts in the digital domain are nowadays implemented with the aid of CMOS technology and binary static logic. Analogue-to-digital conversion (ADC) and digital-to-analogue conversion (DAC) are moved to the edges of the system as much as possible. This approach of mainly digital signal processing has benefited greatly from the previous scaling of semiconductor technology, i.e. from Moore's Law. The technology-driven efficiency gains have offset the ever-increasing demand for processing power. However, Moore's Law has slowed down considerably in more recent times, so that this offset is at risk in the future, especially with the increasing demand for signal processing power in the field of artificial intelligence (AI). In particular, the demands on computing power of deep neural networks (DNN) are increasing much faster than the scaling gains of the underlying CMOS technology. There is therefore an urgent need for new energy-efficient signal processing techniques that can be used in artificial neural networks.

### PRIOR ART

At the present time, artificial neural networks mainly use digital signal processing techniques based on CMOS technology. However, these techniques will reach their limits in the foreseeable future in terms of energy efficiency, with the constantly increasing demands on computing power.

Approaches nowadays include mixed signal processing based on CMOS technology using switched capacitor (SC) charge redistribution techniques for analogue multiplication or summation. These approaches use specially allocated SRAM arrays to store the input values (activations) and weight factors (weights) and a neuron array for the calculation of the scalar product of the input and weight vectors. In the layout of the corresponding integrated circuit, the memory array and neuron array represent locally separated units. For the further reduction of the energy consumption for data transport between these units, it is also of known art to integrate both units into a single unit. This approach is called in-memory processing.

M. Bavandpour et al, “Mixed-Signal Neuromorphic Inference Accelerators: Recent Results and Future Prospects”, in 2018 IEEE International Electron Devices Meeting (IEDM), provide an overview of circuit assemblies for vector-matrix multiplication (VMM). In one of these circuit assemblies, each weight factor is stored in floating-gate cells, which are implemented as a voltage-controlled current source. Here both the input and output values are encoded as pulse widths of voltage pulses.

The object of the present invention is to specify a method for the multiplication and/or formation of a scalar product, which can be implemented in CMOS technology, and enables energy-efficient operation, together with an artificial neural network in which the method is used.

### PRESENTATION OF THE INVENTION

The object is achieved with the methods according to claims 1 and 2, together with the artificial neural networks according to claims 10 and 11. Advantageous configurations of the methods and the artificial neural networks are the subject matter of the dependent patent claims, or can be found in the following description and the examples of embodiment.

In the proposed method for analogue multiplication, as in the method for analogue calculation of a scalar product, a circuit assembly is used, which has a series circuit comprising a first FET and a second FET, or an FET array comprising a plurality of parallel-connected second FETs, serving as a current source, a charging device, and at least one capacitance, which can be precharged by way of the charging device, and can be discharged by way of the series circuit comprising the first FET and the at least one second FET, or FET array. The charging device can be formed simply in terms of a switch, by way of which the capacitance can be connected to a voltage source. To multiply a first value by a second value, the capacitance is first precharged. Here the first value, encoded as the pulse width of a voltage pulse, is applied to the gate of the first FET, and the second value, encoded as a voltage amplitude, is applied to the gate of the second FET, or, encoded as binary voltage amplitudes, to the gates of the parallel-connected second FETs, so that the capacitance is at least partially discharged for a period of time, which is specified by the pulse width of the voltage pulse applied to the gate of the first FET, with a discharge current, which is specified by the voltage amplitude(s) applied to the gate of the second FET, or to the gates of the parallel-connected second FETs. The result of the multiplication can then be determined either from the residual charge or voltage of the capacitance, or—in a configuration described further below, taking into account the sign of the first value—from a voltage difference or charge difference between this capacitance and a further capacitance.

For the calculation of the scalar product, an analogue circuit assembly is used, which has a plurality of parallel-connected series circuits, comprising a first FET and a second FET, or an FET array comprising a plurality of parallel-connected second FETs, serving as a current source, a charging device, and at least one capacitance, which can be precharged by way of the charging device, and can be discharged by way of the series circuits comprising the first FET and the second FET, or FET array. The calculation of a scalar product is hereby understood to be the multiplication of a first value with a second value of a value pair, and the summation of results of the multiplication for a plurality of value pairs, as is the case with the multiplication of two vectors with vector components (as values) in the Cartesian coordinates system. Each of the value pairs of the scalar product is associated with one of the series circuits. The number of series circuits must correspond at least to the number of value pairs of the scalar product, or the vector components of the vectors that are to be multiplied with each other. The capacitance is again first precharged for the calculation of the scalar product. For each of the value pairs, the first value, encoded as the pulse width of a voltage pulse, is applied to the gate of the first FET of the series circuit associated with the respective value pair, and the second value, encoded as the voltage amplitude, is applied to the gate of the second FET, or, encoded as binary voltage amplitudes, is applied to the gates of the second FETs of the associated parallel-connected series circuit, so that the capacitance is at least partially discharged for a period of time, which is specified by the pulse width of the voltage pulse applied to the gate of the first FET of the respective series circuit, with a discharge current, which is specified by the voltage amplitude(s) applied to the gate of the second FET, or to the gates of the parallel-connected second FETs of the respective series circuit. By virtue of the parallel connection of the series circuits, the discharge currents add up according to Kirchhoff's Law. A result of the calculation of the scalar product can then be determined either from the residual charge or voltage of the capacitance or—in the case of a configuration described further below, taking into account the sign of the first value—from a voltage or charge difference between this capacitance and another capacitance.

The proposed methods and neural networks use as field effect transistors (FET), in particular, field effect transistors with an insulating gate (“MISFET”), preferably MOSFETs (metal oxide semiconductor FETS). The capacitance to be discharged can be formed by a capacitor, or also by the parasitic capacitances of the FETs and connection lines used.

The proposed methods thus employ a circuit assembly with a non-linear transfer function, which in the basic embodiment consists of two stacked FETs connected in series and a capacitance. In what follows, this circuit assembly, by virtue of its function, is also referred to as an analogue mixed signal multiplier (AMS). The first multiplicand value is represented as the pulse width of a voltage pulse, which is applied to the gate of the first FET. The second multiplicand is encoded as an analogue voltage, which is applied to the gate of the second FET. An electrical charge packet, which is proportional to the product of the multiplicands, is accumulated on the capacitance, or subtracted from its charge. The connection of further stacked FET series circuits to the capacitance enables the calculation of a scalar product with a minimum number of components. The analogue multiplication can thereby be carried out with a low energy input, as will be explained in more detail later in the examples of embodiment.

Due to the simple construction with FETs and capacitance, the circuit assembly that is used can be implemented in CMOS technology. In contrast to the digital processing techniques with binary signals that have been preferred in electronic signal processing to date, the proposed methods use analogue-mixed signal processing, in which selected electrical nodes carry significantly more information in the analogue domain, which is physically limited only by noise and leakage. The methods enable complex arithmetic operations to be executed on individual capacitive circuit nodes, wherein as few components as possible are involved, and the number of circuit nodes required is drastically reduced compared to digital techniques. The methods and the circuit assemblies used therein can be used particularly advantageously for computing operations in neurons or neuron layers in artificial neural networks. The basic operation of artificial neurons can be mapped onto the proposed AMS circuit assembly with a small number of circuit nodes and components, and implemented with advanced CMOS foundry technology.

In a preferred application of the method for the calculation of a scalar product in an artificial neural network, the circuit assembly, comprising the parallel-connected series circuits, the charging device, and the capacitance, is in each case part of an artificial neuron. Each value pair corresponds to a weight factor and an input value of the artificial neuron. In the preferred configuration, the weight factor is selected as the first value of each value pair, and the input value is selected as the second value. Thus, the weight factors, in each case encoded as the pulse width of a voltage pulse, are applied to the gate of the first

FET, and the input values, encoded as voltage amplitudes, are applied to the gate of the second FET. The weight factors, which are usually available as digital values, must be suitably stored, preferably in appropriate SRAMs, and are in each case converted into the corresponding voltage pulses by means of a digital-time converter (DTC).

In an alternative configuration of the proposed method for the calculation of a scalar product in an artificial neural network, the input value is selected as the first value of the value pair, and the weight factor is selected as the second value. In this case, preferably not just one, but a plurality of second FETs, are used in a parallel circuit, wherein the weight factors are again appropriately stored in a digital manner. The individual binary digits of the respective weight factor—encoded as voltage amplitude—then control the individual second FETs of the FET array, i.e. the parallel circuit of the second FETs. This will be explained in more detail in the example of embodiment.

By the utilisation of two parallel branches with first FETs, which are connected to the at least one second FET, or FET array, in series, and two capacitors, it is also possible to process signed weight factors. Signed input values can also be implemented by means of an appropriate extension of the circuit topology.

With the proposed method for the calculation of the scalar product, and the circuit assembly used in the latter, a neural network can be constructed, in which the neurons are formed by the circuit assemblies. Depending on the configuration, digital-time converters (DTC) must also be implemented. Suitable transfer circuits for the displacement of the charge at the output of a neuron to the inputs of neurons of the respectively subsequent layer may also be required, depending on the configuration. An example of such a transfer circuit can be found in the following examples of embodiment.

A major advantage of the proposed methods, and the circuit assemblies used in the latter, is a very low power consumption. An approximately 500-fold increase in energy efficiency is anticipated for a 28 nm CMOS AMS, compared to a digital 8-bit x 8-bit field multiplier. The circuit assemblies used in the methods can be implemented as commercial standard CMOS technologies, which are also used for a variety of standard and application-specific integrated circuits. The proposed circuit assemblies can thus be used in a hybrid approach together with traditional analogue, RF, digital, and memory, blocks, on a single chip in a “system-on-chip approach”. An AMS IP library enables the design of an AMS co-processor IP, which can be positioned together with other blocks on an application-specific integrated circuit (ASIC), or together with standard COTS digital processor ICs, i.e. together with standard smartphone processors, so as to enable highly energy-efficient shared processing of specific ANN-related tasks. By the utilisation of established standard CMOS logic technology, power-hungry chip-to-chip interfaces for such hybrid systems with conventional digital and new analogue signal processing are avoided. The proposed methods are particularly well suited for applications that do not require exceptional precision. The development of classification tasks based on neural networks can also be supported by the improved energy efficiency of the proposed method, for example in RADAR and LIDAR object recognition for autonomous driving in automobiles, or in mobile, person-assisted speech and image recognition.

### BRIEF DESCRIPTION OF THE FIGURES

The proposed methods, in conjunction with an artificial neural network, are explained once again in more detail below by means of examples of embodiment, in conjunction with the figures. Here:

FIG. 1 shows a detail of three layers from an artificial neural network (sub-figure a)), together with the structure of an artificial neuron (sub-figure b));

FIG. 2 shows an example of the circuit assembly for multiplication (sub-figure a)), together with the circuit assembly for the calculation of a scalar product (sub-figure b)), in accordance with the present invention;

FIG. 3 shows an example of a DTC circuit (sub-figure a)), together with the development of the voltages within the circuit over time (sub-figure b));

FIG. 4 shows an example of an alternative circuit assembly for multiplication in accordance with the present invention;

FIG. 5 shows examples of the implementation of signed weight factors in the proposed circuit assembly;

FIG. 6 shows an example of the matrix-like arrangement of a plurality of the proposed multiplication circuit assemblies for the implementation of a neural layer;

FIG. 7 shows an example of a charge transfer circuit for the transfer of a charge deficit from the output of one neuron to the input of the next neuron; and

FIG. 8 shows an example of the configuration of a neural network in accordance with the present invention.

### PATHS TO THE EXECUTION OF THE INVENTION

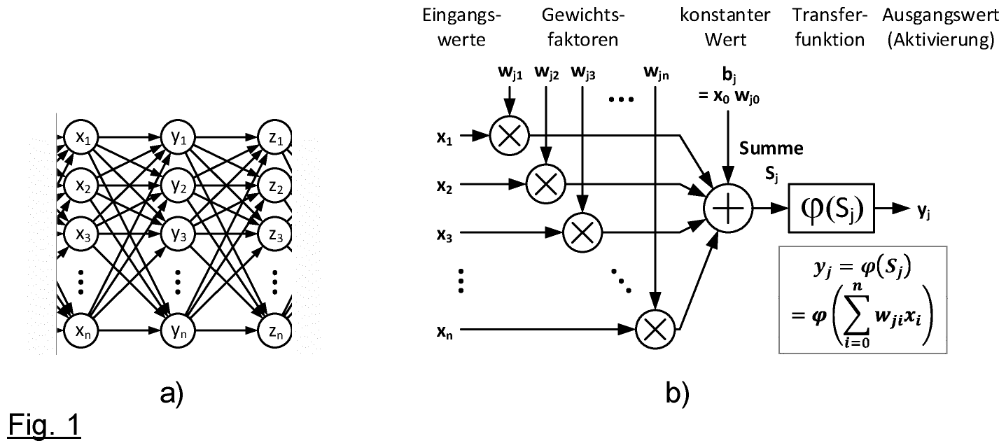

In the following examples, the proposed method, with the associated circuit assembly, is used to calculate scalar products in an artificial neural network. To this end FIG. 1 shows in sub-figure a) a detail with three layers of an artificial neural network. In sub-figure b), the basic structure of an artificial neuron is shown, here for the j^{th} neuron in layer y of the neural network. The input values x₁ to xₙ—that is to say, the activations from the previous layer x—are multiplied by the corresponding weight factors or weights wⱼ₁ to wⱼₙ, and the multiplication results are added, together with a constant value bⱼ=x₀−wⱼ₀. The resulting sum Sⱼ corresponds to the scalar product of the activation vector \vec{X} of the layer x of the neuronal network and the weight vector \vec{W_{J}}, which represents the synaptic weights of the input signals to neuron yⱼ. Furthermore, the sum Sⱼ represents the argument of the transfer function φ(Sⱼ), which generates the final neuron activation yⱼ. Each multiplication xᵢ·wⱼᵢ corresponds to a single synaptic operation.

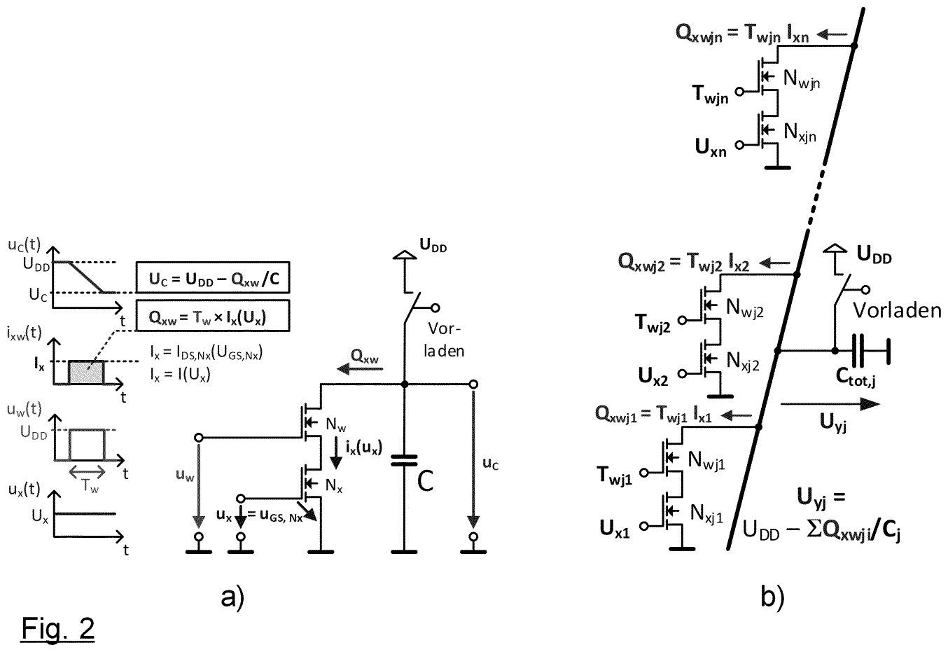

With the proposed method, the calculation of the scalar product that takes place in a neuron is executed in an energy-efficient manner. FIG. 2a illustrates the core schematic of the proposed circuit assembly, i.e. the AMS multiplication cell (AMS: analogue mixed signal multiplier), which is based on two stacked FETs, here MOSFETs, and a capacitor, utilised here as capacitance. Initialisation takes place by precharging the capacitor C to the positive supply voltage U_{DD}. The circuit principle is similar to the precharge and evaluation function in CMOS domino logic. FIG. 2a shows the two series-connected MOSFETs N_{w}, Nₓ, the capacitor C, and the precharging device connected to the supply voltage U_{DD}, here in the form of a switch. The basic schematic of this AMS multiplication cell is used in two different forms of embodiment of the proposed method.

In the preferred configuration, the multiplication result is evaluated as follows. The lower MOSFET Nₓ operates as a current source transistor, which is controlled by its analogue gate-source voltage u_{Gs,Nx}=uₓ, which is provided by way of an input value x, the output of the previous neuron layer. The voltage uₓ controls the drain current iₓ by way of the nonlinear transfer function Iₓ (Uₓ) in accordance with the current equation of the MOSFET. This nonlinearity is a part of the nonlinear transfer function φ of the preceding neuron layer. Since the n-channel MOSFET in the enhancement mode has a threshold voltage greater than 0, a soft rectifier-like transfer function is implemented.

The drain current iₓ is then drawn from the upper pole of the capacitor C only if the stacked MOSFET N_{w} is also conducting. By setting its gate voltage to U_{DD} for a period of time T_{W} corresponding to the weight factor w, the upper MOSFET N_{W} is switched on. The charge Q_{XW} drawn from the output node and the corresponding output voltage U_{C} are given by:

$${Q}_{x w} = {T}_{w} \cdot {I}_{x} ( {U}_{x} ) , \\ {U}_{C} = {U}_{D D} - \frac{{T}_{w} \cdot {I}_{x} ( {U}_{x} )}{C} .$$

The result of the multiplication thus corresponds to the amount of charge Q_{XW} that flows through the series circuit of these two MOSFETs. The temporal relationships of the voltages and currents in this circuit assembly are shown in the left-hand part of FIG. 2a.

FIG. 2b shows the implementation of the proposed circuit assembly for the implementation of an AMS scalar product cell by applying Kirchhoff's current law to a common output node, in which all output currents of the AMS multiplication cells are accumulated. The corresponding parallel connection of a plurality of series circuits of two MOSFETs, the capacitor C, together with the associated charging device, are shown schematically in FIG. 2b. The output voltage U_{yi} is given by:

$${U}_{y j} = {U}_{D D} - \frac{{Q}_{y j}}{{C}_{t ot , j}} = {U}_{D D} - \frac{1}{{C}_{t o t , j}} {\sum }_{i = 0}^{n} {Q}_{x w j i} = {U}_{D D} - \frac{1}{{C}_{t o t , j}} {\sum }_{i = 0}^{n} {T}_{w j i} {I}_{x i} ( {U}_{x i} ) .$$

The artificial neuron function, i.e. a scalar product followed by a non-linear transfer function, is mapped according to simple electrical network principles (i.e. Kirchhoff's Laws) in conjunction with established FET device physics (I_{DS}=f(U_{GS}, U_{DS})). A neuron output activation is implemented along a single line with a series of multipliers.

Analogue multiplication is implemented by the use of only two small MOSFETs. The total capacitance to be charged or discharged during the multiplication process can be limited to values of only 0.6 fF for 300 nm wide MOSFETs Nₓ and N_{y} in 22 nm CMOS. This results in an energy consumption of the multiplication of 0.5 fJ at a supply voltage of 0.8 V. In contrast, the estimated operating energy of an 8-bit×8-bit field multiplier in 28 nm CMOS technology is 8×30 fJ=240 fJ (based on 30 fJ for a single 8-bit adder), resulting in an approximately 500-fold increase in energy efficiency for the proposed AMS.

In the above preferred configuration, the neuron input weight factors wᵢ are represented by the temporal width T_{wi} of current pulses, wherein the current amplitude Iₓᵢ represents the input activations, that is to say, the input values xᵢ (cf. FIG. 1). In order to minimise energy consumption, the individual weight factors are preferably stored locally, directly next to the corresponding AMS multiplier cells. In a standard CMOS process—the target technology for the implementation of circuits in accordance with the present invention—the most efficient and easy-to-use memory implementation is formed by sets of static 6-MOSFET memory cells, which represent binary words or digits. A conversion from the digital binary memory words into temporal pulse widths, that is to say, a digital-time converter (DTC), is therefore required.

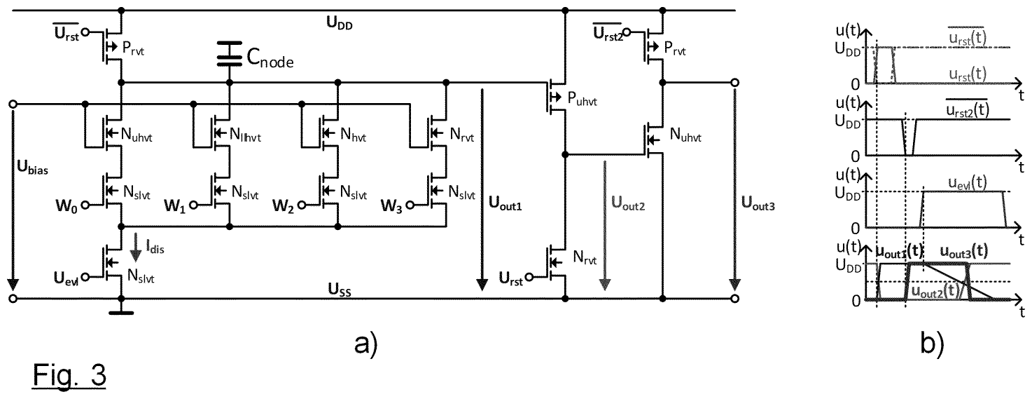

FIG. 3a shows a circuit that executes this conversion, based on the discharge of a parasitic circuit node capacitance C_{node} by a programmable current I_{dis}. The input binary word is represented by the binary signals W₀ to Wₖ, which are delivered by the binary memory cells. These binary signals control the discharge rate of the precharged node Uₒᵤₜ₁. The different discharge currents in the different paths across the switch MOSFETs Nₛₗᵥₜ, at whose gate the binary signals W₀ to Wₖ are applied, are set by the different threshold voltages of the MOSFETs across these switch MOSFETs, as indicated by the abbreviations uhvt (ultra-high threshold voltage), llhvt (high threshold voltage for low leakage current), hvt (high threshold voltage) and rvt (regular threshold voltage). Since the path currents are determined by the threshold voltage and not by the channel width, all MOSFETs in this circuit can have a minimum channel width, resulting in very low dynamic power consumption. Two further precharged and cascaded dynamic amplifier stages with output nodes Uₒᵤₜ₂ and Uₒᵤₜ₃ provide amplification and binary signal level regeneration, when moved into the evaluation mode by signals Uᵣₛₜ and Uᵣₛₜ₂ respectively. The two reset/preload signals Uᵣₛₜ and Uᵣₛₜ₂ and the evaluation signal Uₑᵥₗ are offset in time, as shown in FIG. 3b.

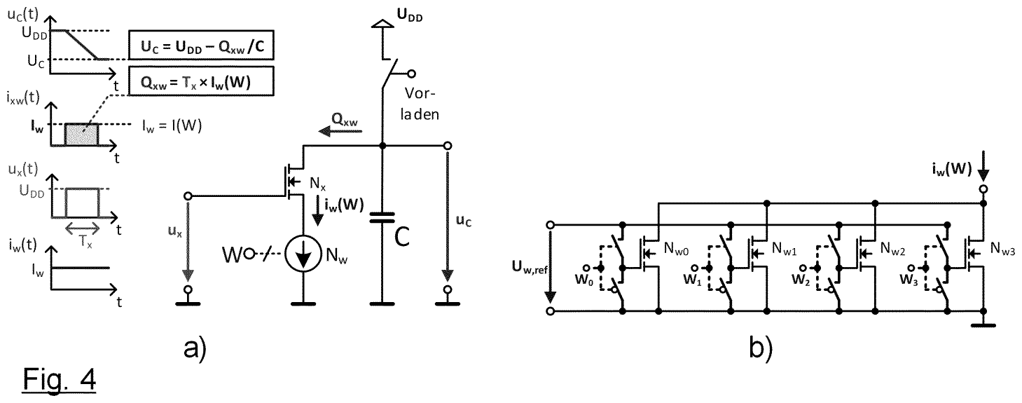

In an alternative form of embodiment, the weight and activation inputs, and thus the roles of the lower and upper MOSFETs in the multiplier evaluation path(s) of FIG. 2 are reversed, as shown in FIG. 4. The weight is now represented by a constant source current I_{w} (cf. FIG. 4a), which is delivered, either by a single lower MOSFET, or by a programmable set of lower MOSFETs N_{wk} with parallel-connected drains and sources, as the current source Nw. FIG. 4b shows an example of the implementation in circuit form of the current source Nw, controlled by the digital word W, by an array of parallel lower MOSFETs N_{wk}. The temporal two-stage activation input uₓ, which is applied to the gate of the upper MOSFET Nₓ, now controls the temporal pulse width Tₓ of the current discharge current i_{w}(t). In the case of the set of a plurality of MOSFETs N_{wk}, the source current I_{w} is again controlled by a local binary weight memory, which supplies the binary signals W₀ to Wₖ.

The advantage of the alternative form of embodiment of FIG. 4 over the preferred form of embodiment of FIG. 2 is that no digital-time converters, or digital-pulse width converters, are required for the weight factors at each position of the mixed signal multiplier. The disadvantage of the alternative form of embodiment compared to the preferred form of embodiment is that charge or voltage pulse width converters are required between the activation outputs (signal domain: analogue voltage or charge) of one neural network layer and the subsequent activation input of the next neural layer (signal domain: pulse width). Such a charge pulse width converter can be implemented after evaluation by recharging the capacitance C by a constant current I_{charge}, starting at a predefined time t₀. A trigger circuit detects the time t₁ of the complete recharge of capacitor C. Between the times t₀ and t₁, a positive voltage u_{y}=U_{DD} is output for the duration t_{y}=t₁−t₀, wherein t_{y}=Q_{y}/I_{charge} is proportional to the charge Q_{y}, which is drawn from C by the AMS circuit.

The AMS multiplier circuits according to FIG. 2a and FIG. 4a operate only with unsigned signals. In the charge equation, both the currents Iₓ (preferred configuration) or I_{W} (alternative configuration), and also the pulse width T_{w} (preferred configuration) or Tₓ (alternative configuration) are positive, resulting in a positive charge Q=I·T drawn from the precharged capacitor C in both configurations. Extensions of the circuit topology based on the AMS multipliers shown in FIG. 2a and FIG. 4a enable the use of signed signals.

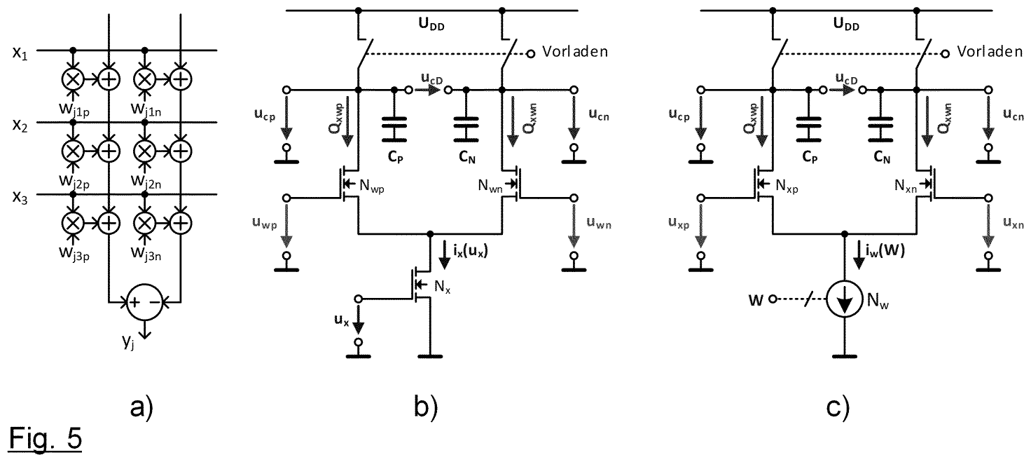

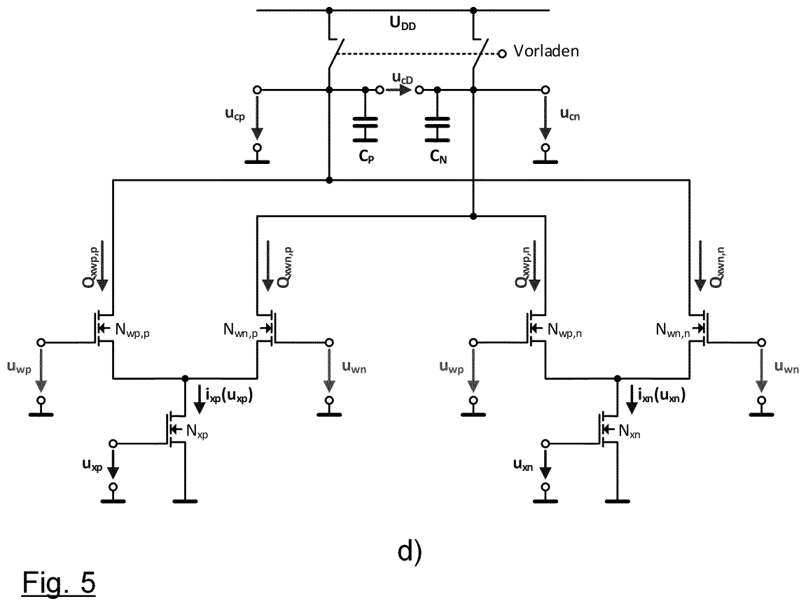

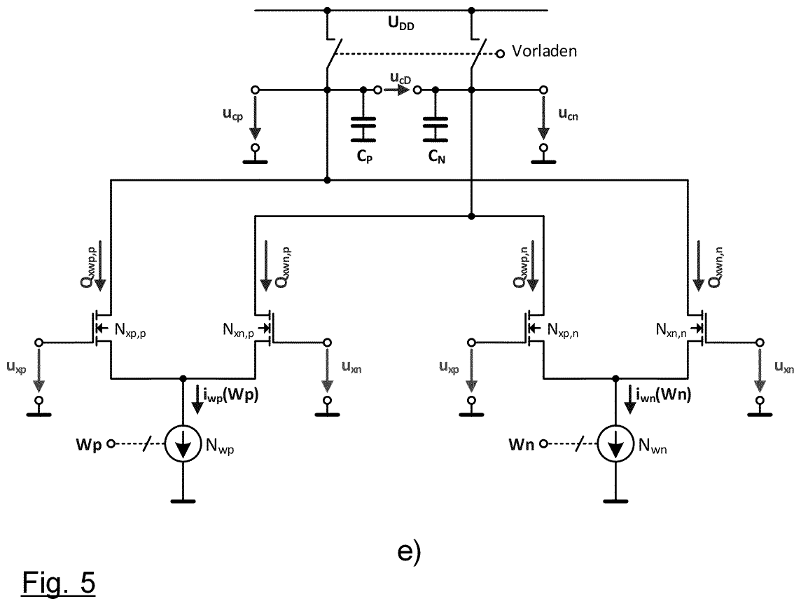

In artificial neural networks, the activation value range is often limited to positive values. However, the weights can be positive or negative. FIG. 5a shows the block diagram for signed weight factors using two signals at the activation output of the neuron. For a positive weight factor wⱼᵢ, the two weight components are set to wⱼᵢₚ=wⱼᵢ and wⱼᵢₙ=0. With a negative weight factor wⱼᵢ, the two weight components are set to wⱼᵢₚ=0 and wⱼᵢₙ=−wⱼᵢ.

FIG. 5b shows the circuit topology for the implementation of a signed weight for the preferred configuration. A pair of MOSFETs N_{wp} and N_{wn} is used, wherein their common source node is connected to the drain of Nₓ, and the pair N_{wp} and N_{wn} replace the single MOSFET N_{w}. The drains of N_{wp} and N_{wn} are connected to two output voltage lines u_{cp} and u_{cn}, respectively, which have the precharged capacitors Cₙ=Cₚ. The final output signal is the voltage difference u_{cD}=u_{cp}−u_{cn}, or the charge difference Q_{D}=Qₚ−Qₙ. A selector connects the output signal Uₒᵤₜ₃ of the DTC of FIG. 3a to the corresponding input u_{wp} or u_{wn} of the differential pair N_{wp/n} of FIG. 5b, depending on the sign of the weight factor. The other input of the differential pair is connected to ground.

FIG. 5c shows the circuit topology for the implementation of a signed weight for the alternative configuration. A pair of MOSFETs Nₓₚ and Nₓₙ is used, wherein their common source node is in turn connected to the drain of N_{w}, and the pair Nₓₚ and Nₓₙ replaces the single MOSFET Nₓ. The drains of Nₓₚ and Nₓₙ are connected to two output voltage lines u_{cp} and u_{cn} respectively, which have the precharged capacitors Cₙ=Cₚ. The final output signal is again the voltage difference u_{cD}=u_{cp}−u_{cn}, or the charge difference Q_{D}=Qₚ−Qₙ. A selector connects the activation input signal uₓ (pulse width domain) from FIG. 3 to the corresponding input uₓₚ or uₓₙ of the difference pair N_{xp/n} from FIG. 5c, depending on the sign of the weight factor. The other input of the differential pair is connected to ground. Here too, N_{w} can be implemented as a programmable current source as shown in FIG. 4b.

To implement both signed weights and signed input activations, that is to say, input values, the circuit topologies of FIGS. 5b and 5c, which represent a single differential topology, must be extended to double differential topologies, and by cross-connection of their outputs to u_{cp} and u_{cn}. For the preferred configuration (FIG. 5b), the single differential pair Nₓ+(N_{wp}−N_{wn}) is doubled to form the double differential topology (Nₓₚ+(N_{wp}−N_{wn})ₚ)−(Nₓₙ+(N_{wp}−N_{wn})ₙ) as shown in FIG. 5d. There is a uₓₚ and uₓₙ input for a signed differential input activation signal (voltage domain), which is connected to the gates of the two Nₓₚ and Nₓₙ current source MOSFETs. The weight u_{wp} (pulse width domain) is connected to both N_{wp,p} and N_{wp,n}, and the weight u_{wn} is connected to both N_{wn,p} and N_{wn,n}.

For the alternative configuration (FIG. 5c), the single differential pair N_{w}+(Nₓₚ−Nₓₙ) is doubled to form the double differential topology (N_{wp}+(Nₓₚ−Nₓₙ)ₚ)−(N_{wn}+(Nₓₚ−Nₓₙ)ₙ), as is shown in FIG. 5e. There is a uₓₚ and uₓₙ differential input for a signed differential input activation signal (pulse width domain); uₓₚ is connected to both N_{xp,p} and N_{xp,n}, and uₓₙ is connected to both N_{xn,p} and N_{xn,n}. N_{wp} is an active current source for positive weight factors, and N_{wn} is an active current source for negative weight factors.

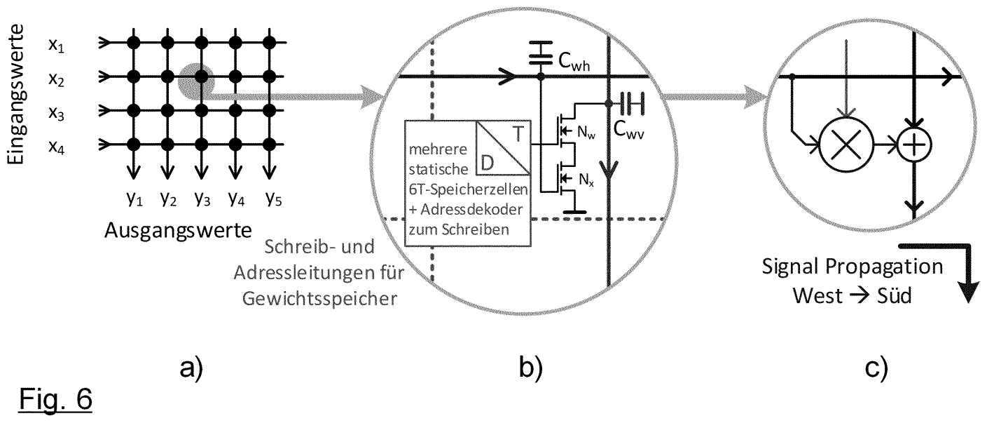

A single neural layer can be implemented by a matrix-like arrangement of a plurality of AMS multiplication cells, or an arrangement of a plurality of scalar product cells next to each other, as is exemplified in FIG. 6. FIG. 6a shows an arrangement of a plurality of AMS scalar product cells arranged next to each other, with n horizontal lines for the input activation vector \vec{X}, m vertical lines for the output activation vector \vec{Y}, and multiplication cells that are positioned at each intersection. Such an arrangement can evaluate one layer of a neural network (cf. FIG. 1a).

The connection of the AMS multiplication cell to a horizontal and a vertical line, and the connection to a local weight memory (+digital-time converter (DTC)) is shown in FIG. 6b. A second overlay grid of horizontal and vertical lines is used to write weight data from the north and east sides of the matrix array to the local weight memory. A signal flow diagram representation of the circuit from FIG. 6b is shown in FIG. 6c.

The matrix arrangement of AMS multiplication cells shown in FIG. 6 is capable of evaluating a single layer in an artificial neural network. For the calculations of a complete artificial neural network, a plurality of the operations executed by the matrix arrangement must be cascaded. This can be done by retransferring the evaluated matrix output signals yᵢ to the matrix inputs xᵢ, or by transferring the evaluated matrix output signals yᵢ to the matrix inputs xᵢ of another (different) matrix. For the preferred configuration, the output and input signals yᵢ and xᵢ are analogue charge (Q) or voltage (Q/C) amplitude domain signals.

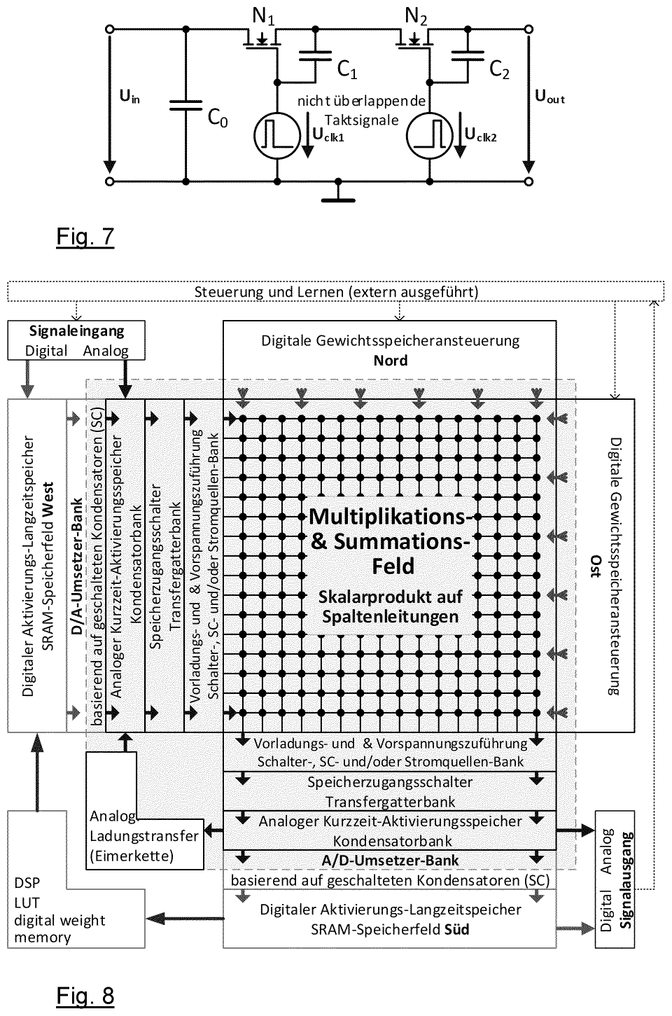

A very efficient method for transferring the analogue amplitude domain signals from the outputs back to the inputs is charge transfer. An example of a corresponding circuit for the charge transfer (transfer of a charge deficit) is shown in FIG. 7. The advantage of this circuit is that no Class A linear amplifiers with static power consumption are used. The charge transfer takes place exclusively by way of clocked common gate circuits with dynamic power consumption.

Alternatively, the charge transfer can also take place by means of analogue voltage signal transfer through linear analogue buffer amplifiers, i.e. based on operational amplifiers with resistors and/or switched capacitors. Digital signal transfer by the interposition of A/D and D/A converters, preferably implemented in terms of energy-efficient SC-based conversion principles such as SAR, and supplemented by means for the processing of large neural layers and the implementation of artificial transfer functions, is also possible. This can be done, for example, by way of digital memories and blocks for digital signal processing.

In the alternative configuration of the proposed method, the output signals yᵢ are signals in the charge (Q) or voltage (Q/C) amplitude domain, while the input signals xᵢ are signals in the pulse width domain. The signal transfer from the matrix outputs yᵢ to the matrix inputs xᵢ therefore requires a charge-to-pulse width converter, as described in one of the preceding sections.

FIG. 8 shows an exemplary implementation of the proposed method in an overall architecture for an integrated neural network coprocessor, which is based on the AMS principles described above (black solid line blocks), supplemented by a parallel digital signal processing path (grey solid line blocks) and an additional external unit for learning purposes (dashed lines). The central part is an n×m AMS multiplication and addition matrix, as has already been explained in connection with FIG. 6a. A forward multiplication and addition unit (AMS multiplication cell, cf. FIGS. 6b and 6c) is located at each crossing point, which enables the matrix to evaluate the neuron layers continuously. Control units for the distributed weight memory are located at the north and east corners of the matrix.

A stack of functional blocks, which are required to preload and write to the analogue horizontal lines, and to read the analogue vertical lines of the multiplication and addition matrix, is located on the west and south sides of the matrix respectively (blocks: preload and bias injection).

Neural network layers. which have more neurons than the matrix row and column numbers n and m respectively, can be supported by analogue charge transfer memory units at the southern output and/or western input edge with additional means for analogue charge addition, as represented by the blocks “transfer gate bank” and “capacitor bank” in FIG. 8.

Energy-efficient charge transfer from the neuron layer activation outputs on the south side to the inputs of the next neuron layer on the west side can be implemented by maintaining the analogue charge domain using the analogue charge transfer circuits described above. In addition, power-efficient SC-based A/D converters can be connected to the south activation output edge, and D/A converters can be connected to the west activation input edge to enable a hybrid evaluation of the neural network, i.e. parts requiring low precision in the analogue path, and parts requiring high precision in an additional digital path. This additional digital path can also be used for the application of more specialised activation transfer functions.

1. Method for the analogue multiplication with a circuit assembly, which has a series circuit comprising a first FET and a second FET, or FET array comprising a plurality of parallel-connected second FETs, serving as a current source, a charging device, and at least one capacitance, which can be precharged by way of the charging device, and can be discharged by way of the series circuit comprising the first FET and the second FET, or FET array, in which
the capacitance is precharged for the execution of a multiplication of a first value by a second value,
the first value, encoded as a pulse width of a voltage pulse, is applied to the gate of the first FET, and
the second value, encoded as a voltage amplitude, is applied to the gate of the second FET, or, encoded as binary voltage amplitudes, is applied to the gates of the parallel-connected second FETs, so that the capacitance is discharged for a period of time, which is specified by the pulse width of the voltage pulse applied to the gate of the first FET, with a discharge current, which is specified by the voltage amplitude(s) applied to the gate of the second FET, or to the gates of the parallel-connected second FETs, and a result of the multiplication can be determined from a residual charge or voltage of the capacitance, or from a voltage difference or charge difference between the latter and a further capacitance.

2. Method for the analogue calculation of a scalar product, which is formed by the multiplication of a first value by a second value of a respective value pair, and the summation of results of the multiplications for a plurality of value pairs, with a circuit assembly, which has a plurality of parallel-connected series circuits comprising a first FET and a second FET, or FET array comprising a plurality of parallel-connected second FETs, serving as a current source, a charging device, and at least one capacitance, which can be precharged by way of the charging device, and can be discharged by way of the series circuits comprising the first FET and the second FET, or FET array, wherein
each of the value pairs is associated with one of the series circuits,
the capacitance is precharged for the calculation of the scalar product
for each of the value pairs, the first value, encoded as a pulse width of a voltage pulse, is applied to the gate of the first FET of the associated series circuit, and
the second value, encoded as a voltage amplitude, is applied to the gate of the second FET, or, encoded as binary voltage amplitudes, to the gates of the parallel-connected second FETs of the associated series circuit,
such that in each case the capacitance is at least partially discharged for a period of time, which is specified by the pulse width of the voltage pulse applied to the gate of the first FET of the respective series circuit, with a discharge current, which is specified by the voltage amplitude(s) applied to the gate of the second FET, or to the gates of the parallel-connected second FETs of the respective series circuit, and a result of the calculation of the scalar product can be determined from a residual charge or voltage of the capacitance, or from a voltage or charge difference between the latter and a further capacitance.

3. Method according to claim 2 in an artificial neural network, in which the circuit assembly represents an artificial neuron, and each value pair is respectively formed by a weight factor and an input value of the artificial neuron.

4. Method according to claim 3,
characterised in that
the weight factor is selected as the first value of each value pair, and the input value is selected as the second value.

5. Method according to claim 3,
characterised in that
the input value is selected as the first value of each value pair, and the weight factor is selected as the second value.

6. Method according to claim 4,
characterised in that
the weight factor is provided as a binary digit sequence, wherein each digit of the digit sequence controls the pulse width at the gate of the first FET by way of a digital-time converter.

7. Method according to claim 5,
characterised in that
the weight factor is provided as a binary digit sequence, wherein each digit of the digit sequence, encoded as a voltage amplitude, controls a second FET of the parallel-connected second FETs.

8. Method according to claim 3,
characterised in that
the parallel-connected series circuits, comprising a first FET and a second FET, or an FET array comprising a plurality of parallel-connected second FETs, serving as a current source, are used in a matrix-like manner at crossing points between horizontal connections for an input vector, and vertical connections for an output vector, in a layer of the artificial neural network, so as to execute calculations of a layer of the artificial neural network.

9. Method according to claim 2,
characterised in that
the circuit assembly for processing signed first values in each of the series circuits comprises two parallel circuit branches, which are serially connected to the second FET, or FET array, and in each case comprise a first FET, wherein a first of the two circuit branches is connected to the capacitance, and a second of the two circuit branches is connected to a second capacitance, which can be precharged by way of the charging device, and can be discharged by way of the series circuit comprising the first FET of the second circuit branch and the second FET, or FET array, wherein the respective first value, encoded as the pulse width of a voltage pulse, is applied, depending on its sign, either to the gate of the first FET of the first circuit branch, or to the gate of the first FET of the second circuit branch, and a result of the multiplication or calculation of the scalar product can be determined from a voltage difference or charge difference between the two capacitors.

10. Neural network with one or more layers of artificial neurons,
in which the neurons of at least one of the layers in each case comprise a circuit assembly comprising:
a plurality of parallel-connected series circuits comprising a first FET and a second FET, serving as a current source,
a charging device, and
a capacitance, which can be precharged by way of the charging device, and can be discharged by way of the series circuits comprising the first FET and the second FET,
wherein components of weight vectors, encoded as pulse widths of a voltage pulse, are applied to gates of the first FETs, and components of input vectors, encoded as voltage amplitudes, are applied to gates of the second FETs.

11. Neural network with one or more layers of artificial neurons,
wherein the neurons of at least one of the layers in each case have a circuit array, which comprises:
a plurality of parallel-connected series circuits comprising a first FET, and a second FET, or an FET array comprising a plurality of parallel-connected second FETs, serving as a current source,
a charging device, and
a capacitance, which can be precharged by way of the charging device, and can be discharged by way of the series circuits of the first FET and the second FET, or FET array,
wherein components of input vectors, encoded as pulse widths of a voltage pulse, are applied to gates of the first FETs, and components of weight vectors, encoded as voltage amplitudes, are applied to gates of the second FETs, or, encoded as binary voltage amplitudes, are applied to the gates of the parallel-connected second FETs of the series circuits.

12. Neural network according to claim 10,
characterised in that transfer circuits are designed between the circuit assemblies of successive lavers of the neural network, for the transfer of a charge deficit of the capacitance of the respective circuit assembly of the preceding layer to gates of the second FETs of the circuit assemblies of the following layer.

13. Neural network according to one of the claim 10, characterised in that
a circuit, for the conversion of digital values into pulse widths of a voltage pulse, is arranged upstream of each circuit assembly.

14. Neural network according to claim 10, characterised in that
the circuit assembly for the processing of signed components of the weight vectors in each of the series circuits has two parallel circuit branches, which are connected to the second FET, or FET array, and in each case have a first FET, wherein a first of the two circuit branches is connected to the capacitance, and a second of the two circuit branches is connected to a second capacitance, which can be precharged by way of the charging means, and can be discharged by way of the series connection of the first FET of the second circuit branch and the second FET, or FET array, wherein the respective component, encoded as the pulse width of a voltage pulse, is applied, depending on its sign, by the control device either to the gate of the first FET of the first circuit branch, or to the gate of the first FET of the second circuit branch.

15. Method according to claim 1,
characterised in that
the circuit assembly for processing signed first values in each of the series circuits comprises two parallel circuit branches, which are serially connected to the second FET, or FET array, and in each case comprise a first FET, wherein a first of the two circuit branches is connected to the capacitance, and a second of the two circuit branches is connected to a second capacitance, which can be precharged by way of the charging device, and can be discharged by way of the series circuit comprising the first FET of the second circuit branch and the second FET, or FET array, wherein the respective first value, encoded as the pulse width of a voltage pulse, is applied, depending on its sign, either to the gate of the first FET of the first circuit branch, or to the gate of the first FET of the second circuit branch, and a result of the multiplication or calculation of the scalar product can be determined from a voltage difference or charge difference between the two capacitors.

16. Neural network according to claim 11,
characterised in that
transfer circuits are designed between the circuit assemblies of successive layers of the neural network, for the transfer of a charge deficit of the capacitance of the respective circuit assembly of the preceding layer to gates of the second FETs of the circuit assemblies of the following layer.

17. Neural network according to claim 11,
characterised in that
a circuit, for the conversion of digital values into pulse widths of a voltage pulse, is arranged upstream of each circuit assembly.

18. Neural network according to claim 11, characterised in that
the circuit assembly for the processing of signed components of the weight vectors in each of the series circuits has two parallel circuit branches, which are connected to the second FET, or FET array, and in each case have a first FET, wherein a first of the two circuit branches is connected to the capacitance, and a second of the two circuit branches is connected to a second capacitance, which can be precharged by way of the charging means, and can be discharged by way of the series connection of the first FET of the second circuit branch and the second FET, or FET array, wherein the respective component, encoded as the pulse width of a voltage pulse, is applied, depending on its sign, by the control device either to the gate of the first FET of the first circuit branch, or to the gate of the first FEY of the second circuit branch.
